(19) United States
(12) Patent Application Publication
(10) Pub. No.: US 2024/0425722 A1
(43) Pub. Date: Dec. 26, 2024

(54) MATERIALS AND METHODS OF PATHOGEN INACTIVATION

(71) Applicant: C-POLAR TECHNOLOGIES, INC., Las Vegas, NV (US)

(72) Inventors: Jianliang GONG, Hong Kong (HK); Chun Yin OR, North Vancouver (CA); Theodore Venners, West Vancouver (CA); Jeanne Moldenhauer, Arlington Heights, IL (US)

(73) Assignee: C-POLAR TECHNOLOGIES, INC., Las Vegas, NV (US)

(21) Appl. No.: 18/751,323

(22) Filed: Jun. 23, 2024

Related U.S. Application Data
(60) Provisional application No. 63/523,355, filed on Jun. 26, 2023.

(51) Int. Cl. C09D 179/02; A01N 33/04; A01P 1/00; C09D 5/24; D06M 10/10; D06M 16/00; D06M 101/20; D06N 3/00; D06N 3/12; G01R 29/12

(52) U.S. Cl. CPC C09D 179/02; A01N 33/04; A01P 1/00; C09D 5/24; D06M 10/10; D06M 16/00; D06N 3/0011; D06N 3/0038; D06N 3/12; G01R 29/12; D06M 2101/20; D06N 2209/04; D06N 2209/1671

(57) ABSTRACT

Materials with uniform electrostatic surface charge for antimicrobial pathogen inactivation meanwhile preserving safety (non-cytotoxicity) for personal and personnel use and methods for manufacturing such antimicrobial materials and uses thereof.

### FIELD OF THE INVENTION

The present invention, NanoFlashing™, involves the even and homogeneous generation of electrostatic charges and mechanoradicals on material surfaces when desired, in a specific range of surface charge density. The present invention further relates to development and manufacture of materials with uniform, safe surface charge density for applications of antimicrobial pathogen inactivation safely, efficiently, and effectively, and features of the material and treatment methods thereof.

### BACKGROUND OF THE INVENTION

The present invention pertains to the field of contact electrification, a natural phenomenon observed in both natural and artificial materials. Contact electrification, as encountered in nature, is spontaneous, uneven, heterogeneous, and uncontrollable. The present invention introduces a novel mechanism, NanoFlashing™, which redefines and expands the understanding of contact electrification (CE). NanoFlashing™ allows for the uniform and homogeneous generation of electrostatic charges and mechanoradicals on material surfaces when desired, in a specific range of surface charge density, yielding a process similar to contact electrification in nature. NanoFlashing™ is different from naturally-occuring contact electrification, in that it can be performed “at will,” at a specific range of surface charge density, and taking into account the significant role of other parameters. The surface charge density is quantified in terms of nanocoulombs per square centimeter (nC/cm²). This unit provides a measure of the amount of electrostatic charge per unit area on a material surface. The invention demonstrates that maintaining a surface charge density evenly and homogeneously between 17 nC/cm²-22 nC/cm² can rapidly inactivate pathogens, including but not limited to, viruses, bacteria, fungi (i.e., yeasts and molds), and pollens within 60 seconds, while being non-cytotoxic to human cells. This discovery opens new possibilities for the use of NanoFlashing™ in various applications, including but not limited to, pathogen inactivation, sterilization, and disinfection.

The natural mechanism of contact electrification involves the generation of electrostatic charges not solely as a direct result of heterolytic bond cleavage, but also from the conversion of highly reactive mechanoradicals, produced by homolytic cleavage of polymer chains during the process of contact electrification. These mechanoradicals, termed as cryptocharges, possess the ability to neutralize active substances in the environment that could potentially induce the decay of electrostatic charges.

In embodiments of the present invention where the surface charge density surpasses a threshold of 22 nC/cm², the material surface begins to manifest cytotoxic properties. This is attributed to the understanding, that above such a threshold level, the surface charge is sufficiently significant to induce inactivation of human cells, thereby impacting the viability of these cells.

### SUMMARY OF THE INVENTION

The structure and system of the present invention provides NanoFlashing™ is different from contact electrification as it occurs in nature, in that it can be performed “at will”, at a specific range of surface charge density, and factors into account the significant role of other parameters and variables. The surface charge density is quantified in terms of nanocoulombs per square centimeter (nC/cm²). This unit provides a measure of the amount of electrostatic charge per unit area on a material surface. The invention demonstrates that maintaining a surface charge density evenly and homogeneously between 17 nC/cm²-22 nC/cm² can rapidly inactivate pathogens, including but not limited to, viruses, bacteria, fungi (i.e., yeasts and molds), and pollens within 60 seconds, while being non-cytotoxic to human cells. This discovery opens new possibilities for the use of NanoFlashing™ in various applications, including but not limited to, pathogen inactivation, sterilization, and disinfection.

### BRIEF DESCRIPTION OF THE DRAWINGS

In the accompanying drawings which form a part of the specification and are to be read in conjunction therewith, and in which like reference numerals are employed to indicate like parts in the various figures:

FIG. 1 is a perspective schematic view of mechanisms for development of uniform effective surface charge density of the materials of the present invention, according to an exemplary embodiment.

FIG. 2 is a schematic view of the process for developing reactive mechanoradicals of optimal surface charge density ranges in the materials of the present invention, according to an exemplary embodiment.

FIG. 3 is a schematic view of apparatus for measuring and testing the surface charge density of test material of the present invention in relation to control reference materials, according to an exemplary embodiment of the present invention.

FIG. 4 is a depiction of mathematical relationship of the contribution to material surface electrostatic charge via the NanoFlashing™ process application to materials per the present invention.

FIG. 5 is an illustrative depiction of the introduction and shaping of surface charge density of a test material of the present invention across the processes of contacting and separation of the material against surface charge inducing elements, according to a preferred embodiment of the present invention.

FIG. 6 is a table presenting antibacterial activity of test Nanoflashing™ materials, embodying the present invention, at a range of concentrations with attendant measurement of continuing viability of test sample cells.

These components in the figures are not necessarily to scale, emphasis instead being placed upon illustrating the principles of the invention. In the figures, identical reference numerals, letters or other identifying symbols may designate corresponding parts throughout the different views.

### DETAILED DESCRIPTION OF THE INVENTION

NanoFlashing™ is a useful innovation related to, yet distinct from, contact electrification as it exists in nature, in that NanoFlashing™ can be performed “at will,” under command and under specific control at a specific range of surface charge densities, further taking into account and incorporating the significant role of other parameters (including ambient manufacture conditions). The surface charge density is quantified in terms of nanocoulombs per square centimeter (nC/cm²). This unit provides a measure of the amount of electrostatic charge per unit area on a material surface. In a preferred embodiment, the present invention demonstrates that maintaining a surface charge density evenly and homogeneously between 17 nC/cm²-22 nC/cm² can rapidly inactivate pathogens, including but not limited to, viruses, bacteria, fungi (i.e., yeasts and molds), and pollens within 60 seconds, while being non-cytotoxic to human cells. This discovery opens new possibilities for the use of NanoFlashing™ in various applications, including but not limited to, pathogen inactivation, sterilization, and disinfection.

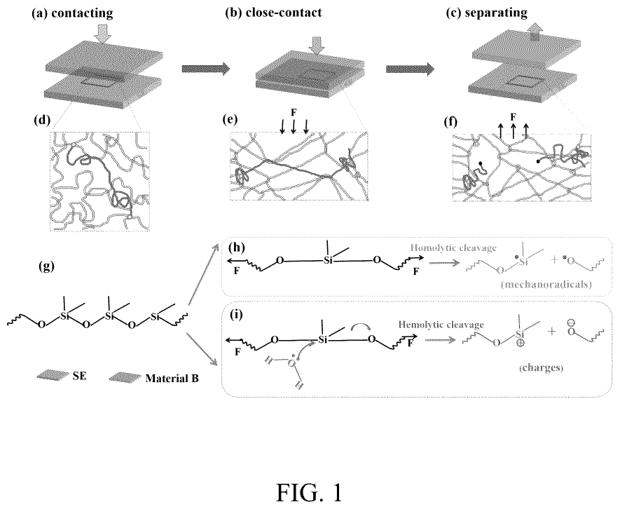

FIG. 1 illustrates the development of uniform electrostatic charges in subject materials of the present invention. The mechanism of contact electrification involves the generation of electrostatic charges not solely as a direct result of heterolytic bond cleavage, but also from the conversion of highly reactive mechanoradicals, produced by homolytic cleavage of polymer chains during the process of contact electrification. These mechanoradicals, also termed as cryptocharges, possess the ability to neutralize active substances in the environment that could potentially induce the decay of electrostatic charges.

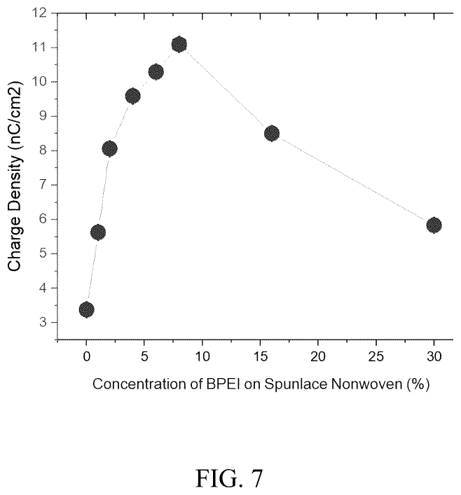

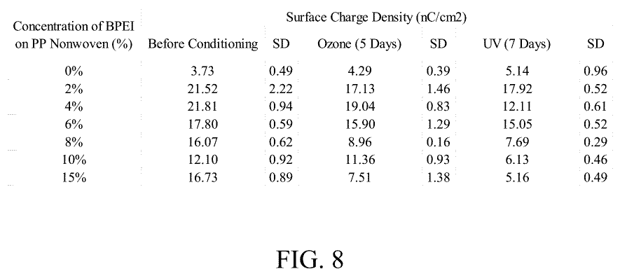

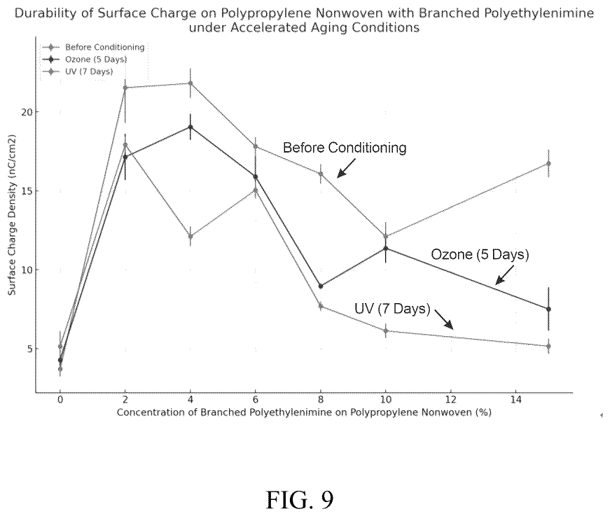

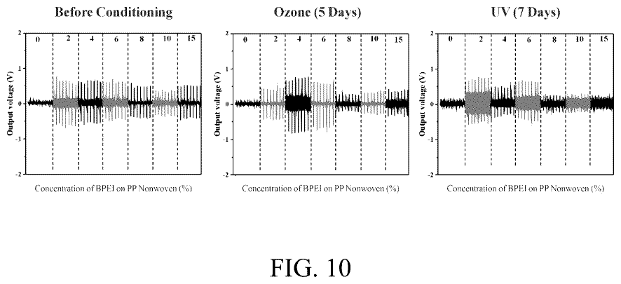

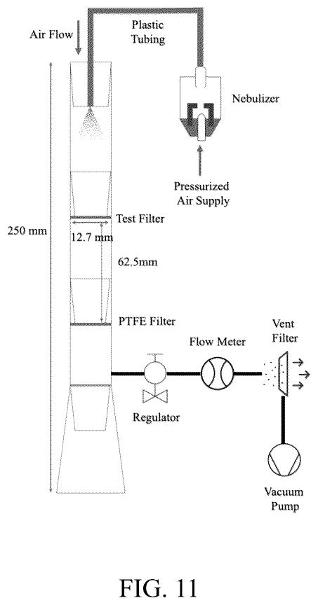

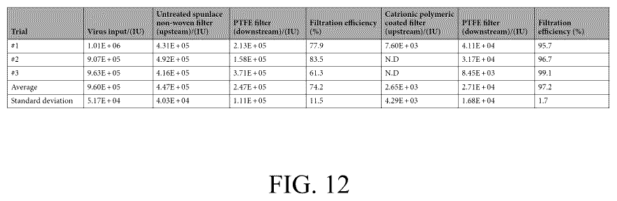

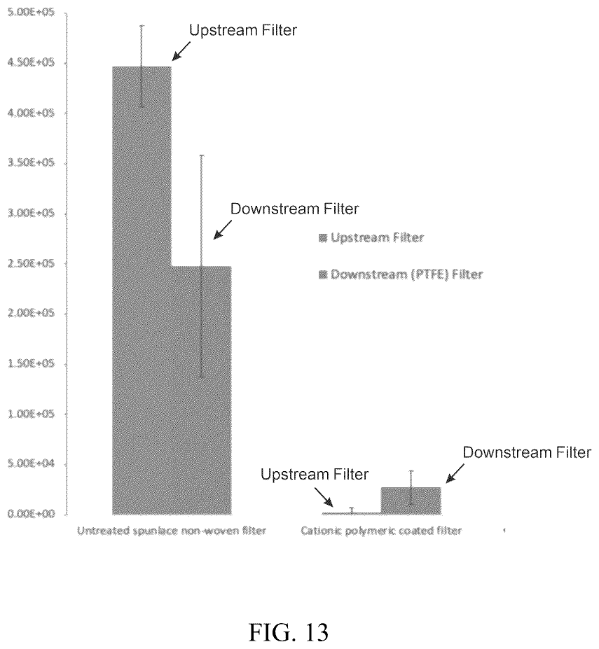

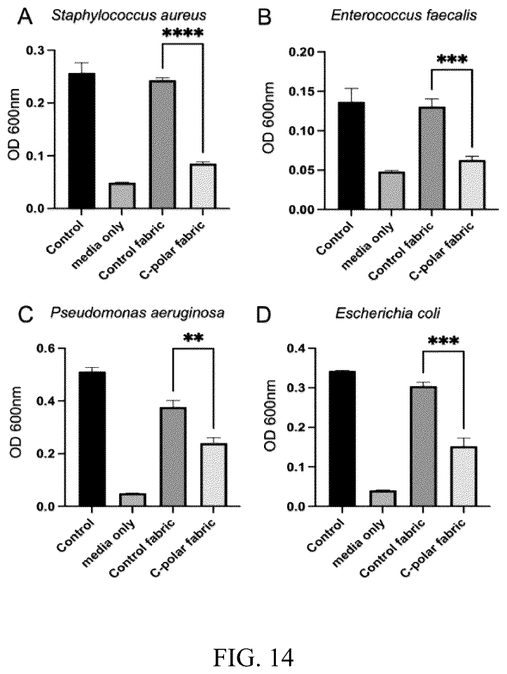

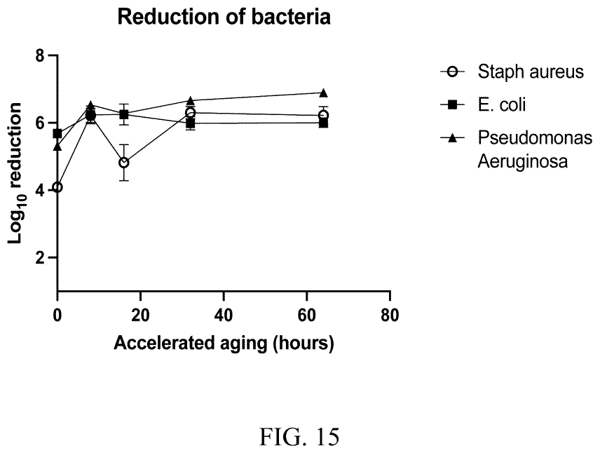

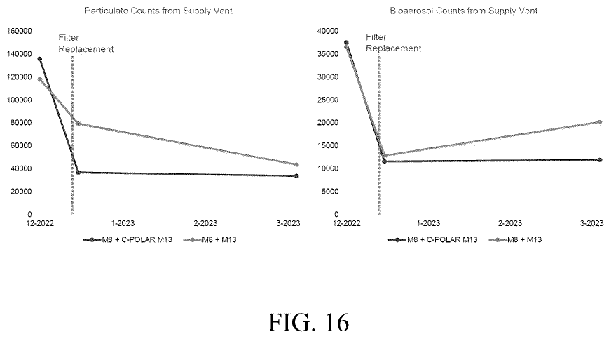

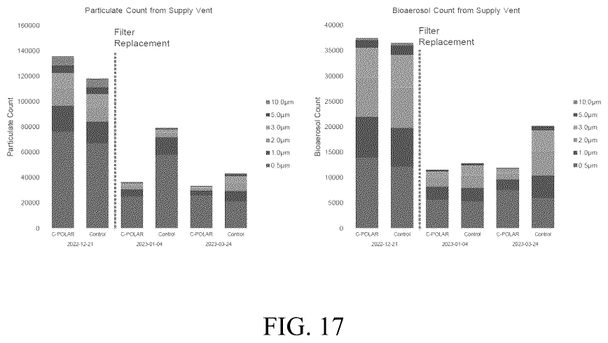

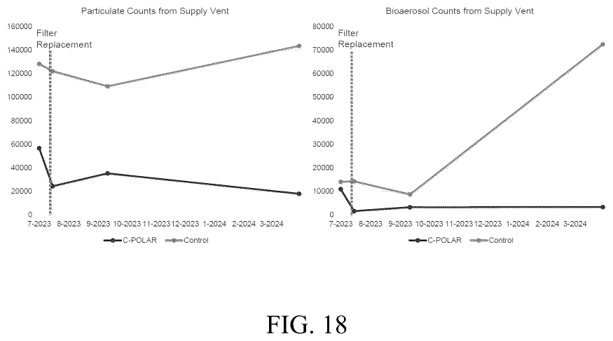

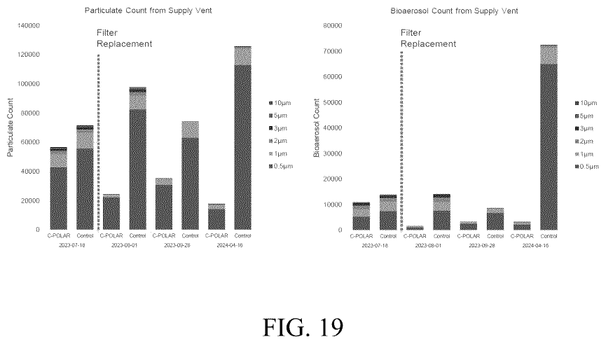

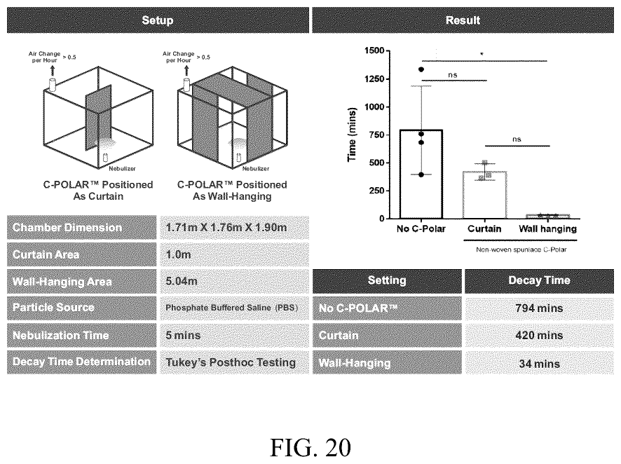

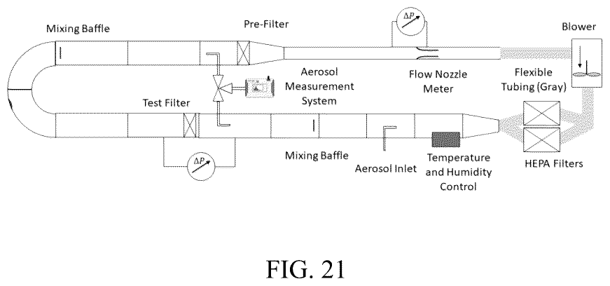

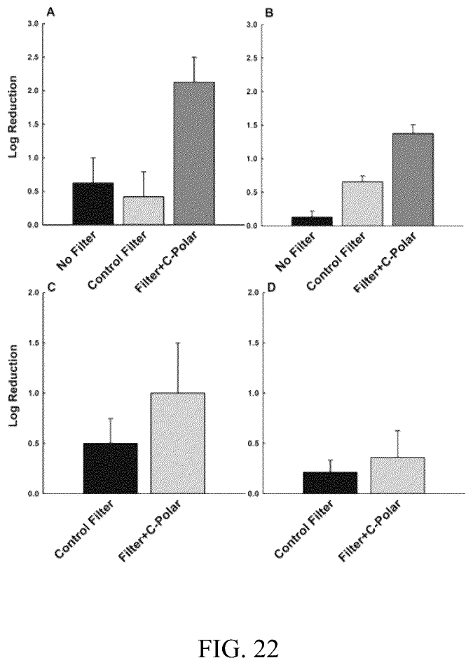

In circumstances where the surface charge density surpasses a threshold of 22 nC/cm², the material surface begins to manifest cytotoxic properties (this is also depicted in FIG. 6). This cytotoxicity is attributed to the fact that beyond such a threshold level, the surface charge is sufficiently significant to induce inactivation of human cells, thereby impacting the viability of these cells.

The presence of other substances can trigger a cascade of chain reactions, leading to the generation of new macromolecular charges and radicals. This results in a pronounced electrostatic phenomenon and mechanoradical chemical reaction observable at a macroscopic level. This understanding of the contact electrification process and the role of other substances are a significant departure from traditional theories and provides a new framework for harnessing the power of contact electrification. As further depicted in FIG. 1, the schematic depiction illustrates and demonstrates the process of the natural contact electrification on the generation of electrostatic charges and mechanoradicals through the heterolytic bond cleavage and homolytic cleavage of polymer chains, using silicone elastomers, a kind of non-adhesive polymer, in contact with another non-adhesive polymer, such as PTFE, as an exemplary embodiment.

Additionally, as further illustrated in FIG. 1, the processes of direct chemical bond cleavage mode for the formation of mechanoradicals and electrostatic charges on the surface of silicone elastomers during the contact electrification process are presented. Namely, in step (a) of FIG. 1, the silicone elastomer is contacted with another non-adhesive polymer, for example, PTFE, by external force. In step (b), the silicone elastomer reaches the closest contact with another non-adhesive polymer, for example, PTFE. In step (c), the silicone elastomer separates from contact with the other non-adhesive polymer (e.g., PTFE) via an external force. As presented in (d), the polymer chains of the silicone elastomer are coiled and flexible prior to the contact process. In step (e), the polymer chains of the silicone elastomer are stretched during the deformation process caused by the close proximity/contact of step (b) above. In step (f), the polymer chains of the silicone elastomer are broken at point of closest proximity/contact between the materials, and the polymer chains of the silicone elastomer recover to coiled and flexible states once again following a separation (between the materials) step. In (g), typical chemical structures of polymer chains of silicone elastomers of the invention are presented. In (h), mechanoradicals generated via homolytic cleavage of the polymer chains of silicone elastomer chains of the present invention are depicted. In (i), electrostatic charges generated via heterolytic cleavage of the polymer chains of silicone elastomer of the present invention are depicted.

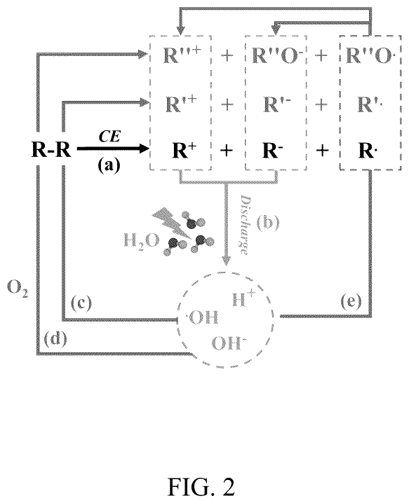

In FIG. 2, a schematic flow diagram illustration depicting and demonstrating the cascade of chain reactions, leading to the generation of new macromolecular charges and radicals, in conventional contact electrification. Specifically, in FIG. 2, the flow diagram for contract electrification and mechanisms for the generation of mechanoradicals and electrostatic charges in an open, conventional environment, are identified stepwise. In step (a), the generation of primary mechanoradicals, symbolized as (R·), and electrostatic charges (R+ and R−), is presented. This process is achieved through the direct homolytic and heterolytic bond cleavage of polymer chains, representing a fundamental step in contact electrification. In step (b), the generation of new macromolecular radicals, denoted as R′· and charges R′+ and R′− are depicted. These entities originate from the polymer substrate that has been attacked by small active substances, further advancing the generative mechanisms. In step (c), the enhanced generation of electrostatic charges from mechanoradicals, also termed herein as cryptocharges, is presented. This enhancement is achieved with the assistance of small active molecules, providing an insight into the final steps of the process and concluding the sequence.

In contrast, the NanoFlashing™ mechanism of the present invention, represents an engineered emulation of this natural process. It operates independently of material exchange, ion exchange, electron exchange, and does not involve toxicity or consumption of chemicals. This characteristic renders the natural mechanisms of contact electrification a highly efficient and environmentally benign method for the generation and utilization of electrostatic charges evenly and homogeneously into a specific surface charge density.

The invention further delineates the importance of firmly, evenly, and homogeneously bonding one or more non-adhesive polymers onto the material surface. This secure attachment is a critical aspect of the NanoFlashing™, as it facilitates the efficient conversion of external forces into surface charge, a key component of the NanoFlashing™ mechanism. Through the use of one or more bonding mechanisms, including but not limited to, covalent bonding, hydrogen bonding, physical entanglement, Van der Waals Forces, ionic bonding, pi-pi stacking, dipole-dipole interactions, metal coordination bond, hydrophobic interactions, electrostatic interactions, steric entrapment, adsorption, cross-linking, self-assembly, layer-by-layer assembly, grafting-to approach, grafting-from approach, supramolecular chemistry, click chemistry, polymer brushes, sol-gel process, thermal bonding, ultrasonic bonding, plasma treatment, photopolymerization, reversible deactivation radical polymerization, mechanochemical bonding, electrospinning, chemisorption, spin coating, spray coating, Langmuir Blodgett films, self-stratification, microcontact printing, dip-pen nanolithography, molecular imprinting, and others as appropriate, the non-adhesive polymer is robustly affixed to the material surface, ensuring the even and homogenous stability and functionality even under the influence of external frictional or mechanical forces, including but not limited to, static friction, kinetic friction, rolling friction, fluid friction, internal friction, dry friction, lubricated friction, skin friction, stick-slip friction, coulomb friction, stiction, tension force, normal force, air resistance force, applied force, spring force, gravitational force, centripetal force, torque, magnetic force, electric force, nuclear force, elastic force, inertial force, buoyant force, weight, drag force, impulse force, restoring force, centrifugal force, contact force, conservative force, non-conservative force, resistive force, pseudo force and resultant force. In the absence of robust bonding, the non-adhesive polymer may be subject to movement or displacement under the influence of frictional force or mechanical force, thereby impeding the energy conversion process. This secure attachment facilitates the efficient conversion of external forces into surface charge, which is a key aspect of the NanoFlashing™ mechanism.

This discovery of the role of non-adhesive polymers, refers to a polymer material with inherently low or no adhesion characteristics, due to its specific chemical composition, physical properties, or surface characteristics, such polymers do not readily adhere or bond to other substances under typical conditions, and this non-stick property makes it resistant to the bonding of substances on its surface, thus enabling the emulation of contact electrification under conditions frictional force or mechanical force. Non-adhesive polymers include but not limited to Polytetrafluoroethylene (PTFE), Polyvinylidene fluoride (PVDF), Polydimethylsiloxane (PDMS), Ethylene tetrafluoroethylene (ETFE), Polyether ether ketone (PEEK), Perfluoroalkoxy alkane (PFA), Polychlorotrifluoroethylene (PCTFE), Fluorinated Ethylene Propylene (FEP), Polyimides, Polyphenylsulfone (PPSU), Polyetherimide, Polyethylenimine (PEI), Polypropylene (PP), High-density Polyethylene (HDPE), Low-density Polyethylene (LDPE), Polystyrene (PS), Polycarbonate (PC), Polyvinyl chloride (PVC), Polyethylene Terephthalate (PET), Polybutylene Terephthalate (PBT), Polyphenylene Sulfide (PPS), Polysulfone (PSU), Polyaryletherketone (PAEK), Polynorbornene, Polyarylamide (PARA), Acrylonitrile Butadiene Styrene (ABS), Polyoxymethylene (POM), Polyvinyl Alcohol (PVA), Polyvinylidene Chloride (PVDC), Polymethyl Methacrylate (PMMA), Polybutadiene (PBD), Polyisobutylene (PIB), Polyvinyl Acetate (PVAc), Polyurethane (PU), Polytetrahydrofuran (PolyTHF), Styrene-butadiene (SBR), Polyphenylene Oxide (PPO), Polyphthalamide (PPA), Polybutene (PB), Polyisoprene (PI), Polyether Block Amide (PEBA), Polybenzimidazole (PBI), Polyethylene Naphthalate (PEN), Ethylene-Vinyl Alcohol (EVOH), Polyvinyl Butyral (PVB), Polydicyclopentadiene (pDCPD), Polysilazane, Ethylene Propylene Diene Monomer (EPDM), Ethylene Vinyl Acetate (EVA), Polycaprolactone (PCL), Polyglycolide or Polyglycolic Acid (PGA), Polylactic Acid (PLA), Polyhydroxyalkanoates (PHA), Polyethyleneimine (PEI) in dry form, Poly(dimethylaminoethyl methacrylate) (PDMAEMA) in dry form, Chitosan in dry form, Polyallylamine in dry form, Poly-L-lysine (PLL) in dry form, Polyvinylpyridinium in dry form, Poly(2-(dimethylamino)ethyl methacrylate) (PDMAEMA) in dry form, Poly(diallyldimethylammonium chloride) (PDDA) in dry form, Poly(amidoamine) (PAMAM) in dry form, Polyguanidinium oxanorbornene (PGON) in dry form, Poly([2-(methacryloyloxy)ethyl]trimethylammonium chloride) (PMETAC) in dry form, Poly(diallylamine hydrochloride) (PDAH) in dry form, Poly(4-vinylbenzyltrimethylammonium chloride) (PVBTMAC) in dry form, Poly(N,N,N-trimethylaminoethyl methacrylate chloride) (PTMAEMC) in dry form, Poly(amido amine) (PAMAM) in dry form, Poly(N-[3-(dimethylamino)propyl] methacrylamide) (PDMAPMA) in dry form, Poly(N,N-dimethylaminoethyl methacrylate) (PDMAEMA) in dry form, Poly(N-(3-sulfopropyl)-N-(methacryloxyethyl)-N,N-dimethylammonium betaine) (PSMPDMDAB) in dry form, Poly(N-[3-(Dimethylamino)propyl]acrylamide) (PDAPA) in dry form, Poly(2-(methacryloyloxy)ethyltrimethylammonium chloride) (PMETAC) in dry form, Poly(N,N-dimethyl-3,5-dimethylene piperidinium chloride) (PDDPC) in dry form, Poly(3-acrylamidopropyl)trimethylammonium chloride (PAPTAC) in dry form, Polyvinylamine (PVAm) in dry form, Poly(1-vinylimidazole) (PVI) in dry form, Poly(N,N-dimethyl-3,5-dimethylenepiperidinium chloride) (Poly DMDAAC) in dry form, Poly(N-Cyclohexylaminoethyl methacrylate chloride) (PCHAEMC) in dry form, Poly(N,N-diethylaminoethyl methacrylate) (PDEAEMA) in dry form, Poly(N-2-Hydroxypropyl Methacrylamide) (PHPMA) in dry form, Poly(N-isopropylacrylamide) (PNIPAM) in dry form, Polyvinylbenzyltrimethylammonium chloride (PVBTC) in dry form, Polyquaternium compounds in dry form, Poly(dimethyldiallylammonium chloride) (PDMDAAC) in dry form, Polyvinyl pyrrolidone (PVP) in dry form, Polystyrene sulfonate (PSS) in dry form, Poly(2-diisopropylaminoethyl methacrylate) (PDPA) in dry form, Poly(methyl chloride quarternized dimethylaminoethyl methacrylate) (PMCDMAEMA) in dry form, Poly(acryloyloxyethyltrimethyl ammonium chloride) (PAETAC) in dry form, Poly(Diallyl dimethyl ammonium Chloride) (PDADMAC) in dry form, Poly(2-(Methacryloyloxy)ethyl)trimethylammonium Methyl Sulfate (PMETMS) in dry form, Polystyrene sulfonate (PSS) in dry form, Polyacrylic acid (PAA) in dry form, Alginate in dry form, Poly(methacrylic acid) (PMAA) in dry form, Hyaluronic acid in dry form, Poly(vinyl sulfate) (PVS) in dry form, Polyvinylphosphonic acid (PVPA) in dry form, Poly(aspartic acid) (PASA) in dry form and Carboxymethyl cellulose (CMC) in dry form.

In the event that the subject polymer exhibits adhesive characteristics, said polymer is likely to adhere to the surface upon which a frictional or mechanical force is exerted. Consequently, during the separation process between adhesive polymer and surface material, the polymer chain remains unbroken, as the adhesive polymer sticks to the surface material, unable to trigger the cascade of chain reactions of the generation of electrostatic charges.

The importance of their tight bonding and non-adhesive polymers on the material surface under frictional force or mechanical force provides a new strategy for designing materials and devices that can effectively harness the power of NanoFlashing™. This strategy can be applied in various fields, including but not limited to, healthcare, food safety, water treatment, air purification, and others as appropriate.

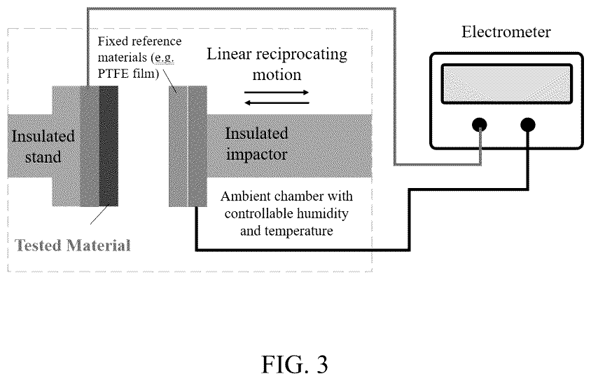

As depicted in FIG. 3, the invention also includes a method for measuring the surface charge density via NanoFlashing™ on various surfaces. This method involves controlling the ambient conditions at a given temperature and relative humidity, fixing two electrodes on an insulating stand and impactor, and connecting them to an electrometer with conductive wires. The main principle for measuring immobile surface charges generated on the tested materials in specific surface area, via NanoFlashing™, is to measure the mobile electrons transferred between two electrodes based on the effect of NanoFlashing™.

As depicted in FIG. 3, the following steps outline in detail the procedure of measuring surface charge density via NanoFlashing™: (1) Control the ambient conditions to a specific temperature and relative humidity, such as 25° C. and 75% RH. (2) Affix two electrodes onto an insulating stand and an impactor. Connect these electrodes to an electrometer using conductive wires. (3) Secure a test material, of a predetermined size, such as 2 cm×2 cm, onto the surface of the electrode mounted on the insulating impactor. (4) Introduce the reference material, such as PTFE, ensuring uniform thickness, onto the surface of the electrode mounted on the insulating stand. (5) Activate a linear reciprocating motion device to impact the tested material with the reference material at a predetermined impact force and frequency, such as 40N and 1 Hz. (6) Initiate the electrometer, such as a 6514 System Electrometer, and associated software to monitor electrostatic charge variations in a Coulomb measurement mode. A series of square waves with a frequency matching the externally applied forces will typically be observed. (7) Document the increase of charge with the progression of impact times until a maximum value is reached. After this point, utilize the software to record the data for further analysis. (8) Import the recorded data into a data processing software, such as Origin, and calculate the electrostatic charge difference before and after separation to obtain σ_{CE}. (9) To measure the electrostatic charge of a new tested material, deactivate the impactor, replace the old sample on the insulating stand with the new one, and repeat steps 4, 5, 7, and 8.

As further depicted in FIG. 3, the setup for the measurement of the surface charge density via NanoFlashing™ is illustrated. In particular, the Insulated Stand serves to hold testing material, that is, the material to be measured for the surface charge density via NanoFlashing™. The Fixed reference material is non-adhesive material to be used to impact the test material. The Insulated Impactor impacts/collides the test material with the reference material repeatedly. The Ambient chamber is used for controlling the temperature and relative humidity of the measurement test conditions. The Electrometer monitors the electrostatic charge variations in a Column measurement mode.

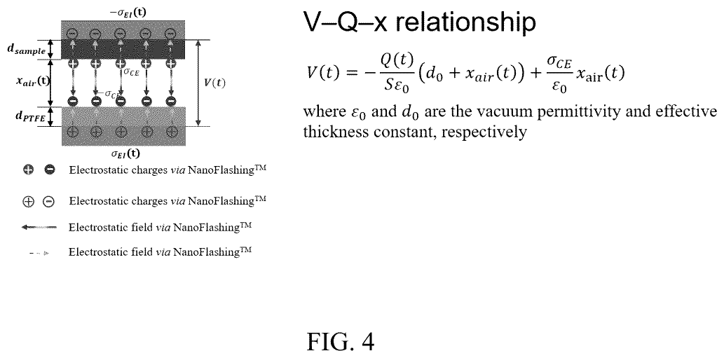

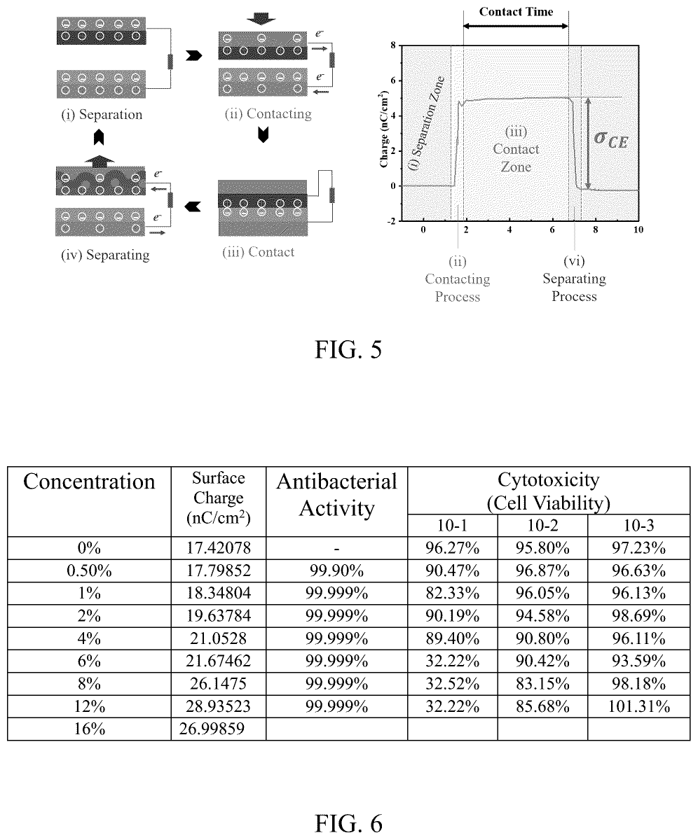

FIG. 4 and FIG. 5 illustrate the measurement of the surface charge density of the NanoFlashing™ treated subject materials and, in particular, the V-Q-x relationship thereto. In particular, the formula of FIG. 4 defines the number of transferred electrons between the two electrodes as Q, and it is equal to the instantaneous number of charges induced on the electrode via NanoFlashing™. Further, as the transferred or induced charge (Q(t)) is determined by the electrostatic potential difference (V(t)) between the two electrodes, it increases with the increase of the separation distance (Xair(t)) during the separating process, while it decreases during the subsequent contacting process. This relationship, namely, the V-Q-x relationship, is presented in FIG. 4, with the referents or equation elements particularly assigned as follows: V(t) is the Electrostatic potential difference (V(t)) between the two electrodes via the NanoFlashing™ process of the invention; Q(t) is the instantaneous amount of the induced surface charge via the NanoFlashing™ process of the present invention; S is Surface Area; ε₀ represents Vacuum permissiveness; do represents the effective thickness constant of the tested material; Xₐᵢᵣ(t) represents the separation distance (Xₐᵢᵣ(t)) during the separating process; σ_{CE} is the induced surface charge density during the contacting or separating process via the NanoFlashing™ process of the present invention, as depicted in FIG. 4 and FIG. 5.

As depicted in FIG. 6, the efficacious antibacterial activity of test Nanoflashing™ materials at a range of concentrations is demonstrated concurrent with a demonstration that at surface charge levels between 17 nC/cm²-22 nC/cm², the application of the test materials presents minimal risk of cytotoxicity to treated cells. This presents a promising avenue for development and further study of the antibacterial activity and pathogen activity of the Nanoflashing™ materials in a broad array of sanitary health-oriented commercial applications.

In conclusion, the present invention is an innovative approach to harnessing the phenomenon of contact electrification via a newly discovered mechanism referred to herein as a NanoFlashing™ process. The NanoFlashing™ process enables the homogenous generation of electrostatic charges and mechanoradicals on material surfaces in specific surface charge densities, revolutionizing our understanding of contact electrification and its potential applications. This novel technique takes into account the often-overlooked impact of ambient substances, resulting in a refined and improved method of manipulating contact electrification for practical use. The critical uniform and homogeneous surface charge density for pathogen inactivation is found to be between 17 nC/cm²-22 nC/cm², leading to potential applications in areas such as sterilization, disinfection, and pathogen inactivation.

The implications of the present invention are significant, extending the reach of contact electrification from purely theoretical exploration to tangible, practical applications, with a current emphasis on pathogen inactivation, healthcare, food safety, water treatment, air purification and others fields as will be found to be promising and applicable. The methods, materials, and apparatus for implementing NanoFlashing™ offer an effective, non-cytotoxic, and environmentally friendly alternative to existing techniques for pathogen inactivation. Furthermore, the development of a reliable method to measure surface charge density facilitates the design and optimization of materials and devices that leverage the power of contact electrification. This invention, therefore, represents a substantial advancement in the understanding and application of contact electrification.

While various embodiments of the invention have been described, it will be apparent to those of ordinary skill in the art that many more embodiments and implementations are possible that are within the scope of this invention. In addition, the various features, elements, and embodiments described herein may be claimed or combined in any combination or arrangement.

What is claimed is:

1. A method for generating long-term sustained electrostatic charges on insulating material surfaces, comprising:
applying a cationic polymeric material to an insulating base material, wherein the insulating base material has a low dielectric constant, and wherein the cationic polymeric material is applied via dipping, spraying, vapor deposition, foam application, brush or roller application, or precision deposition;
pressing the treated material and verifying even distribution of the polymer, strong physical bonding of the polymer to the substrate and structural alignment of polymer chains;
removing excess solution; and
drying the pressed treated material under controlled conditions whereby the cationic polymer is stably adhered to the base material and long-term sustained electrostatic charge is evenly distributed upon the material surface.

2. The method of claim 1, wherein the surface charge density of the resultant material surface is between 2-35 nC/cm².

3. The method of claim 2, wherein the insulating base material comprises material selected from the group consisting of:
polytetrafluoroethylene (PTFE), polyvinylidene fluoride (PVDF), polydimethylsiloxane (PDMS), ethylene tetrafluoroethylene (ETFE), polyether ether ketone (PEEK), perfluoroalkoxy alkane (PFA), polychlorotrifluoroethylene (PCTFE), fluorinated ethylene propylene (FEP), polyimides, polyphenylsulfone (PPSU), polyetherimide, polyethylenimine (PEI), polypropylene (PP), high-density polyethylene (HDPE), low-density polyethylene (LDPE), polystyrene (PS), polycarbonate (PC), polyvinyl chloride (PVC), polyethylene terephthalate (PET), polybutylene terephthalate (PBT), polyphenylene sulfide (PPS), polysulfone (PSU), polyaryletherketone (PAEK), polynorbornene, polyarylamide (PARA), acrylonitrile butadiene styrene (ABS), polyoxymethylene (POM), polyvinyl alcohol (PVA), polyvinylidene chloride (PVDC), polymethyl methacrylate (PMMA), polybutadiene (PBD), polyisobutylene (PIB), polyvinyl acetate (PVAc), polyurethane (PU), polytetrahydrofuran (PolyTHF), styrene-butadiene (SBR), polyphenylene oxide (PPO), polyphthalamide (PPA), polybutene (PB), polyisoprene (PI), polyether block amide (PEBA), polybenzimidazole (PBI), polyethylene naphthalate (PEN), ethylene-vinyl alcohol (EVOH), polyvinyl butyral (PVB), polydicyclopentadiene (pDCPD), polysiloxane, ethylene propylene diene monomer (EPDM), ethylene vinyl acetate (EVA), polycaprolactone (PCL), polyglycolide or polyglycolic acid (PGA), polylactic acid (PLA), polyhydroxyalkanoates (PHA), polyethyleneimine (PEI) in dry form, poly(dimethylaminoethyl methacrylate) (PDMAEMA) in dry form, chitosan in dry form, polyallylamine in dry form, poly-L-lysine (PLL) in dry form, polyvinylpyridinium in dry form, poly(2-(dimethylamino)ethyl methacrylate) (PDMAEMA) in dry form, poly(diallyldimethylammonium chloride) (PDDA) in dry form, poly(amidoamine) (PAMAM) in dry form, polyguanidinium oxanorbornene (PGON) in dry form, poly([2-(methacryloyloxy)ethyl]trimethylammonium chloride) (PMETAC) in dry form, poly(diallylamine hydrochloride) (PDAH) in dry form, poly(4-vinylbenzyltrimethylammonium chloride) (PVBTMAC) in dry form, poly(N,N,N-trimethylaminoethyl methacrylate chloride) (PTMAEMC) in dry form, poly(amido amine) (PAMAM) in dry form, poly(N-[3-(dimethylamino)propyl] methacrylamide) (PDMAPMA) in dry form, poly(N,N-dimethylaminoethyl methacrylate) (PDMAEMA) in dry form, poly(N-(3-sulfopropyl)-N-(methacryloxyethyl)-N,N-dimethylammonium betaine) (PSMPDMDAB) in dry form, poly(N-[3-(Dimethylamino)propyl]acrylamide) (PDAPA) in dry form, poly(2-(methacryloyloxy)ethyltrimethylammonium chloride) (PMETAC) in dry form, poly(N,N-dimethyl-3,5-dimethylene piperidinium chloride) (PDDPC) in dry form, poly(3-acrylamidopropyl)trimethylammonium chloride (PAPTAC) in dry form, polyvinylamine (PVAm) in dry form, poly(1-vinylimidazole) (PVI) in dry form, poly(N,N-dimethyl-3,5-dimethylenepiperidinium chloride) (Poly DMDAAC) in dry form, poly(N-Cyclohexylaminoethyl methacrylate chloride) (PCHAEMC) in dry form, poly(N,N-diethylaminoethyl methacrylate) (PDEAEMA) in dry form, poly(N-2-hydroxypropyl methacrylamide) (PHPMA) in dry form, poly(N-isopropylacrylamide) (PNIPAM) in dry form, polyvinylbenzyltrimethylammonium chloride (PVBTC) in dry form, polyquaternium compounds in dry form, poly(dimethyldiallylammonium chloride) (PDMDAAC) in dry form, polyvinyl pyrrolidone (PVP) in dry form, polystyrene sulfonate (PSS) in dry form, poly(2-diisopropylaminoethyl methacrylate) (PDPA) in dry form, poly(methyl chloride quarternized dimethylaminoethyl methacrylate) (PMCDMAEMA) in dry form, poly(acryloyloxyethyltrimethyl ammonium chloride) (PAETAC) in dry form, poly(diallyl dimethyl ammonium chloride) (PDADMAC) in dry form, poly(2-(methacryloyloxy)ethyl)trimethylammonium methyl sulfate (PMETMS) in dry form, polystyrene sulfonate (PSS) in dry form, polyacrylic acid (PAA) in dry form, alginate in dry form, poly(methacrylic acid) (PMAA) in dry form, hyaluronic acid in dry form, poly(vinyl sulfate) (PVS) in dry form, polyvinylphosphonic acid (PVPA) in dry form, poly(aspartic acid) (PASA) in dry form, carboxymethyl cellulose (CMC) in dry form, and combinations thereof.

4. The method of claim 1, wherein the cationic polymer is selected from the group consisting of: gelatin, chitosan, cationic peptides, cationic cyclodextrin, cationic dextran, cationic cellulose, branched polyethylenimine, linear polyethylenimine, polylysine, polyamidoamine, poly(amino-co-ester)s, poly [2-(N,N-dimethylamino)ethyl methacrylate], and combinations thereof.

5. The method of claim 1, wherein the pressing step involves applying a specific pressure uniformly across the surface of the treated material for a controlled duration.

6. The method of claim 1, wherein the drying process conditions of temperature, duration, and humidity are optimized for the specific materials used.

7. A long-term durably electrostatically-charged material with a long-term durable electrostatically-charged surface, produced by a process of steps, comprising:
applying a cationic polymeric material to a substrate material, wherein the substrate material has a low dielectric constant, and wherein the cationic polymeric material is applied via dipping, spraying, vapor deposition, foam application, brush or roller application, or precision deposition;
pressing the treated material and verifying even distribution of the polymer, strong physical bonding of the polymer to the substrate and structural alignment of polymer chains;
removing excess solution; and
drying the pressed treated material under controlled conditions whereby the cationic polymer is stably adhered to the base material and long-term sustained electrostatic charge is evenly distributed upon the material surface.

8. The material of claim 7, wherein the long-term sustained surface charge density of the material surface is between 2-35 nC/cm².

9. The material of claim 8, wherein the substrate material comprises material selected from the group consisting of:
polytetrafluoroethylene (PTFE), polyvinylidene fluoride (PVDF), polydimethylsiloxane (PDMS), ethylene tetrafluoroethylene (ETFE), polyether ether ketone (PEEK), perfluoroalkoxy alkane (PFA), polychlorotrifluoroethylene (PCTFE), fluorinated ethylene propylene (FEP), polyimides, polyphenylsulfone (PPSU), polyetherimide, polyethylenimine (PEI), polypropylene (PP), high-density polyethylene (HDPE), low-density polyethylene (LDPE), polystyrene (PS), polycarbonate (PC), polyvinyl chloride (PVC), polyethylene terephthalate (PET), polybutylene terephthalate (PBT), polyphenylene sulfide (PPS), polysulfone (PSU), polyaryletherketone (PAEK), polynorbornene, polyarylamide (PARA), acrylonitrile butadiene styrene (ABS), polyoxymethylene (POM), polyvinyl alcohol (PVA), polyvinylidene chloride (PVDC), polymethyl methacrylate (PMMA), polybutadiene (PBD), polyisobutylene (PIB), polyvinyl acetate (PVAc), polyurethane (PU), polytetrahydrofuran (PolyTHF), styrene-butadiene (SBR), polyphenylene oxide (PPO), polyphthalamide (PPA), polybutene (PB), polyisoprene (PI), polyether block amide (PEBA), polybenzimidazole (PBI), polyethylene naphthalate (PEN), ethylene-vinyl alcohol (EVOH), polyvinyl butyral (PVB), polydicyclopentadiene (pDCPD), polysiloxane, ethylene propylene diene monomer (EPDM), ethylene vinyl acetate (EVA), polycaprolactone (PCL), polyglycolide or polyglycolic acid (PGA), polylactic acid (PLA), polyhydroxyalkanoates (PHA), polyethyleneimine (PEI) in dry form, poly(dimethylaminoethyl methacrylate) (PDMAEMA) in dry form, chitosan in dry form, polyallylamine in dry form, poly-L-lysine (PLL) in dry form, polyvinylpyridinium in dry form, poly(2-(dimethylamino)ethyl methacrylate) (PDMAEMA) in dry form, poly(diallyldimethylammonium chloride) (PDDA) in dry form, poly(amidoamine) (PAMAM) in dry form, polyguanidinium oxanorbornene (PGON) in dry form, poly([2-(methacryloyloxy)ethyl]trimethylammonium chloride) (PMETAC) in dry form, poly(diallylamine hydrochloride) (PDAH) in dry form, poly(4-vinylbenzyltrimethylammonium chloride) (PVBTMAC) in dry form, poly(N,N,N-trimethylaminoethyl methacrylate chloride) (PTMAEMC) in dry form, poly(amido amine) (PAMAM) in dry form, poly(N-[3-(dimethylamino)propyl] methacrylamide) (PDMAPMA) in dry form, poly(N,N-dimethylaminoethyl methacrylate) (PDMAEMA) in dry form, poly(N-(3-sulfopropyl)-N-(methacryloxyethyl)-N,N-dimethylammonium betaine) (PSMPDMDAB) in dry form, poly(N-[3-(Dimethylamino)propyl]acrylamide) (PDAPA) in dry form, poly(2-(methacryloyloxy)ethyltrimethylammonium chloride) (PMETAC) in dry form, poly(N,N-dimethyl-3,5-dimethylene piperidinium chloride) (PDDPC) in dry form, poly(3-acrylamidopropyl)trimethylammonium chloride (PAPTAC) in dry form, polyvinylamine (PVAm) in dry form, poly(1-vinylimidazole) (PVI) in dry form, poly(N,N-dimethyl-3,5-dimethylenepiperidinium chloride) (Poly DMDAAC) in dry form, poly(N-Cyclohexylaminoethyl methacrylate chloride) (PCHAEMC) in dry form, poly(N,N-diethylaminoethyl methacrylate) (PDEAEMA) in dry form, poly(N-2-hydroxypropyl methacrylamide) (PHPMA) in dry form, poly(N-isopropylacrylamide) (PNIPAM) in dry form, polyvinylbenzyltrimethylammonium chloride (PVBTC) in dry form, polyquaternium compounds in dry form, poly(dimethyldiallylammonium chloride) (PDMDAAC) in dry form, polyvinyl pyrrolidone (PVP) in dry form, polystyrene sulfonate (PSS) in dry form, poly(2-diisopropylaminoethyl methacrylate) (PDPA) in dry form, poly(methyl chloride quarternized dimethylaminoethyl methacrylate) (PMCDMAEMA) in dry form, poly(acryloyloxyethyltrimethyl ammonium chloride) (PAETAC) in dry form, poly(diallyl dimethyl ammonium chloride) (PDADMAC) in dry form, poly(2-(methacryloyloxy)ethyl)trimethylammonium methyl sulfate (PMETMS) in dry form, polystyrene sulfonate (PSS) in dry form, polyacrylic acid (PAA) in dry form, alginate in dry form, poly(methacrylic acid) (PMAA) in dry form, hyaluronic acid in dry form, poly(vinyl sulfate) (PVS) in dry form, polyvinylphosphonic acid (PVPA) in dry form, poly(aspartic acid) (PASA) in dry form, carboxymethyl cellulose (CMC) in dry form, and combinations thereof.

10. The material of claim 7, wherein the cationic polymer is selected from the group consisting of: gelatin, chitosan, cationic peptides, cationic cyclodextrin, cationic dextran, cationic cellulose, branched polyethylenimine, linear polyethylenimine, polylysine, polyamidoamine, poly(amino-co-ester)s, poly [2-(N,N-dimethylamino)ethyl methacrylate], and combinations thereof.

11. The material of claim 7, wherein the pressing step involves applying a specific pressure uniformly across the surface of the treated material for a controlled duration.

12. The material of claim 7, wherein the drying process conditions of temperature, duration, and humidity are optimized for the specific materials used.

13. The material of claim 7, wherein the material primarily comprises material selected from the group consisting of: textiles, woven fabrics, non-woven fabrics, foams, sponges, carbon, aggregate material, sand, rigid plastics, flexible films, powders, granules, elastomers, ceramics, composite materials, and glass.

14. The material of claim 7, wherein the material retains significant charge density and electrostatic properties upon application of UV radiation, ozone exposure, and high temperature.

15. The material of claim 7, wherein the material exhibits antimicrobial properties against gram-positive and gram-negative bacteria.

16. The material of claim 15, further wherein the material retains antimicrobial properties in dynamic local environmental conditions, comprising: fast-moving air flow, fast-moving water flow, blood flow, or material motion.

17. A method for measuring surface charge density of materials, comprising:
establishing controlled humidity and temperature in an ambient test chamber;
engaging in controlled repeated contact and separation between a test material and a reference material via a linear reciprocating motion device in the ambient test chamber;
and measuring charge variations with an electrometer in the ambient chamber.
